(19) United States
(12) Patent Application Publication
(10) Pub. No.: US 2009/0140433 A1
(43) Pub. Date: Jun. 4, 2009

(54) MEMS chip-to-chip interconnects

(75) Inventors: David M. Bloom, Jackson, WY (US); Matthew A. Leone, Jackson, WY (US); Richard Yeh, Sunnyvale, CA (US)

Correspondence Address: MORRISON ULMAN;NUPAT, LLC, PO BOX 1811, MOUNTAIN VIEW, CA, 94042-1811, US

(73) Assignee: ALCES TECHNOLOGY, INC., Jackson, WY (US)

(21) Appl. No.: 12/276,123

(22) Filed: Nov. 21, 2008

Related U.S. Application Data
(60) Provisional application No. 61/004,941, filed on Nov. 30, 2007.

(51) Int. Cl. H01L 23/48; H01L 21/4763

(52) U.S. Cl. 257/773; 438/618; 257/E21.532; 257/E23.169

(57) ABSTRACT

A chip-to-chip interconnect system suited for MEMS that do not require low-resistance connections is described. The interconnects may be fabricated simultaneously with MEMS ribbon structures such as are found in MEMS optical modulators.

### RELATED APPLICATIONS

This application claims priority benefit from U.S. provisional patent application No. 61/004,941, filed on Nov. 30, 2007, which is incorporated herein by reference.

### TECHNICAL FIELD

The disclosure is related to chip-to-chip interconnects for micro-electromechanical systems.

### BACKGROUND

Micro-electromechanical systems (MEMS) are found in diverse applications including accelerometers, gyroscopes, pressure sensors, optical switches and attenuators, biological lab-on-a-chip devices, and optical displays. The last category, displays, may be distinguished from the others by the large number of individually addressed, movable elements in the MEMS devices. A two-dimensional display modulator, such as a digital micro-mirror device for example, contains as many elements as pixels in the displayed image. The number of elements in scanned, one-dimensional modulators is reduced to approximately the square root of the number of pixels, but this still often implies thousands of electrical signals to drive the modulator. Flip-chip integration of MEMS with CMOS (complementary metal oxide semiconductor) de-multiplex circuits reduces the number of pins on the final package to a manageable number.

Flip-chip techniques, such as solder bump flip-chip, have been highly successful for creating electronic multi-chip packages and even in CMOS/MEMS integration prototyping. However, there is much room for improvement. Under-bump metallization adds process steps and potential contamination to MEMS devices. Solder bump connections are permanent (which precludes swapping MEMS devices for testing), non-compliant, and often require under-fill to increase fatigue life. Furthermore, the bumps take up valuable wafer real estate. In one linear light modulator prototype chip 99% of the chip area is devoted to flip-chip interconnects!

One possible solution to the interconnect problem is micro-spring based connections. Palo Alto Research Center and others have developed metal, low-resistance micro-springs for chip-to-chip interconnects as a possible replacement for conventional flip-chip techniques. Less than one ohm interconnect resistance has been achieved and further work will drive the resistance even lower. “The spring resistance of 0.54 Ω. while adequate for many applications, should be reduced for high current or high frequency applications.” (E. Chow, et al., IEEE Trans. Components and Packaging Tech., Dec. 2006, p. 802.)

Metal springs offer a high-density interconnect system, yet they are not ideal for MEMS display chips. The additional steps required to make them add complexity to MEMS processes. What is needed is a MEMS chip-to-chip interconnect technology that is easily integrated with existing MEMS process flows and is designed for MEMS' unique electrical requirements.

### BRIEF DESCRIPTION OF THE DRAWINGS

The drawings are heuristic for clarity.

FIGS. 1A and 1B are scanning electron microscope (SEM) images of MEMS ribbon devices.

FIG. 2 shows a MEMS ribbon device connected to CMOS chips by MEMS micro-springs.

FIG. 3 shows a MEMS ribbon device connected to a CMOS chip by MEMS micro-springs.

FIGS. 4A and 4B show MEMS micro-springs bending in response to material stresses.

FIGS. 5A, 5B, and 5C show the tip of a MEMS micro-spring as it comes in contact with and departs from a surface.

FIGS. 6A and 6B show a MEMS micro-spring in contact with a surface.

FIGS. 7A-7F are process steps for making MEMS micro-springs with post-release metallization.

FIGS. 8A-8D are process steps for making MEMS micro-springs with pre-release metallization.

FIGS. 9A-9D are SEM images of MEMS micro-springs.

### DETAILED DESCRIPTION

A MEMS chip-to-chip interconnect system is now described. This micro-compliant interconnect mechanism is suited for MEMS that do not require low-resistance or high electrical current connections. Examples of such devices are MEMS optical ribbon devices such as those described in U.S. Pat. Nos. 5,311,360, 7,054,051 and related patents. MEMS optical ribbon devices are used in a variety of MEMS optical modulators including grating light modulators, differential interferometric light modulators, and polarization light modulators. MEMS ribbon devices have high switching speeds which makes them suitable for scanned, linear array modulator architectures.

Linear MEMS optical modulators containing more than 4,000 ribbon elements have been constructed. Operation of these devices requires electrical connections to each ribbon (or, in some cases, every other ribbon). Ribbon devices present a capacitive load, however, so low-resistance connections are not necessary, nor is the capability to carry a high electrical current. The interconnect mechanisms described here can be fabricated simultaneously with ribbon devices using the same steps. Ribbon and interconnect fabrication adds only two mask steps to a conventional CMOS process. No electroplating is needed, for example.

The MEMS chip-to-chip interconnect system described here drastically reduces the wafer area required for linear array, MEMS ribbon optical modulators and thereby reduces the cost to manufacture them. The interconnects are compliant and support multiple connect/disconnect cycles for chip testing as ceramic mechanical layers are not subject to problems associated with metal fatigue. MEMS micro-springs used here are similar in some ways to previous micro-spring interconnects; however, they are based on insulating cantilevers coated with a thin layer of metal. Thus they are a poor choice when either low-resistance or high electrical current capacity is a design goal, yet serve well for capacitive devices.

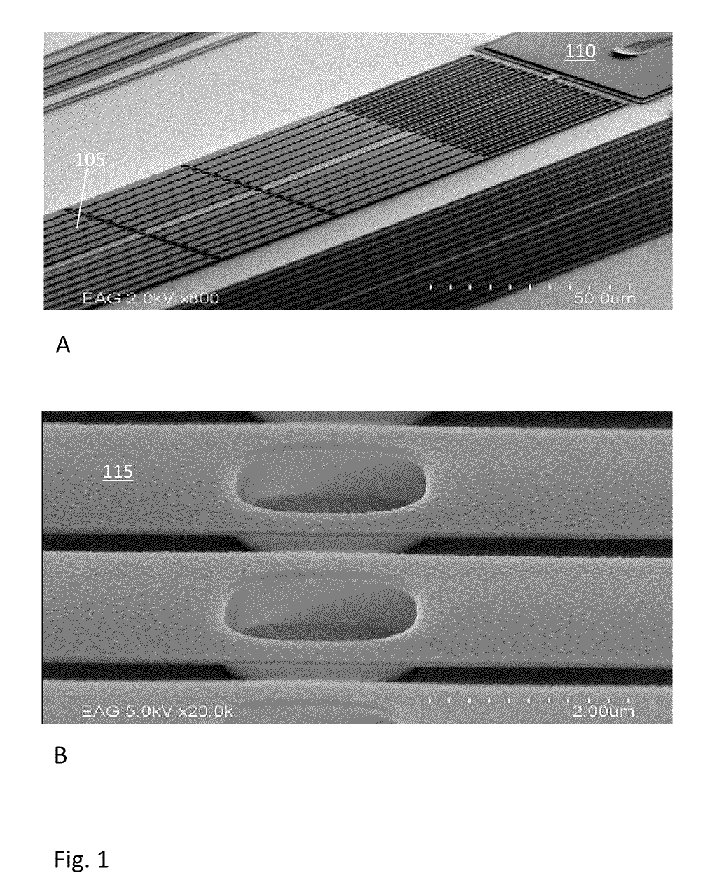

FIGS. 1A and 1B are scanning electron microscope (SEM) images of MEMS ribbon devices. Scale bars are provided at the lower right of each figure. The structure in FIG. 1A is a ribbon test structure. Fifteen ribbons, such as ribbon 105, are in the structure, but only one of them is connected to bond pad 110, and only part of each ribbon is visible in the image. FIG. 1B offers a zoomed in view of ribbons, such as ribbon 115, near a ribbon support post.

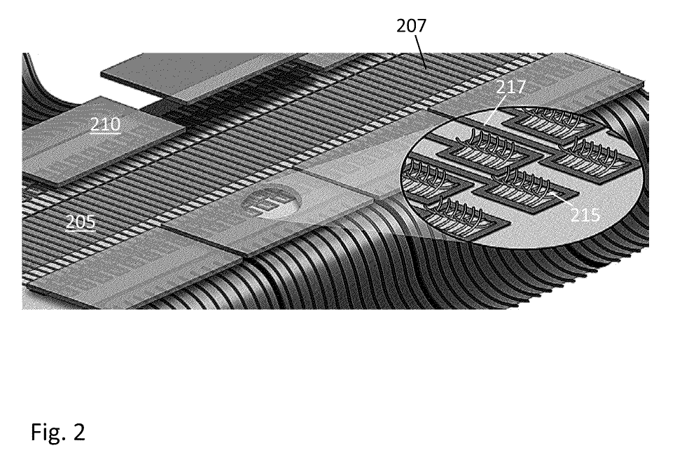

FIG. 2 shows a MEMS ribbon device connected to CMOS chips by MEMS micro-springs. In FIG. 2, ribbon device 205 comprises many ribbons such as ribbon 207. CMOS chips, such as chip 210, are connected to the ribbons by MEMS micro-springs such as springs 215. In FIG. 2, each ribbon is connected to a dozen MEMS micro-springs by a conductor such as 217.

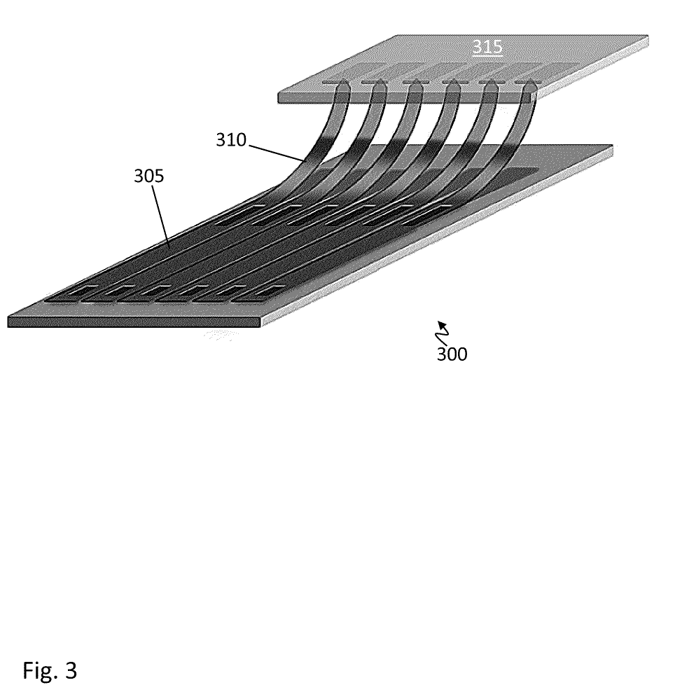

FIG. 3 shows MEMS micro-springs connecting a MEMS chip to a CMOS chip. In FIG. 3, ribbon device 300 comprises ribbons such as ribbon 305. Ribbon 305 is directly connected to MEMS micro-spring 310 which contacts chip 315. In fact, as discussed in detail below, ribbon 305 and spring 310 can be made in the same MEMS fabrication process.

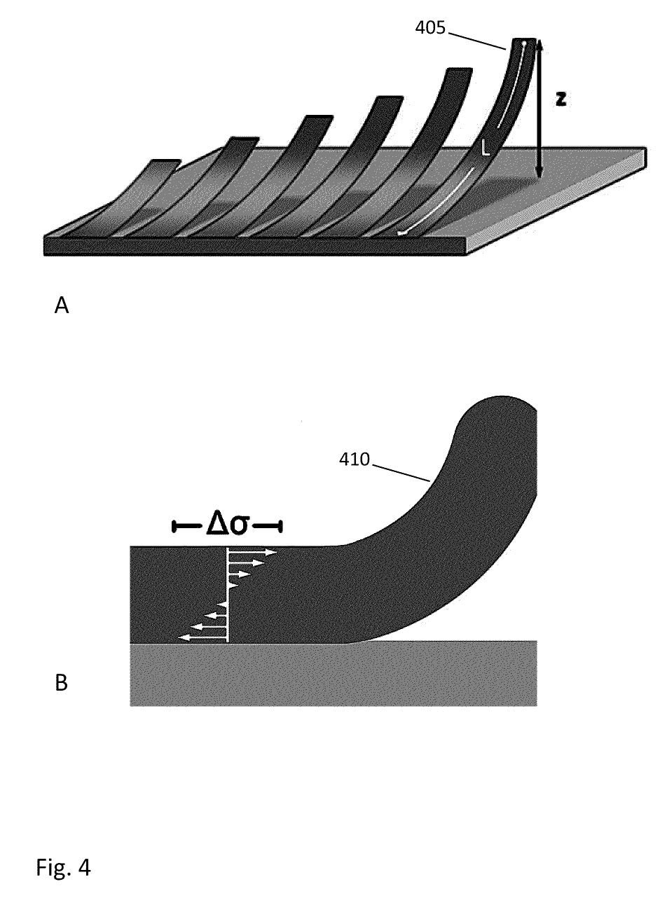

FIGS. 4A and 4B show MEMS micro-springs bending upward in response to material stresses. In FIG. 4A, spring 405 has length L and is deflected by distance z. In FIG. 4B, spring 410 is shown deflected under the influence of internal stress gradient Δσ. The relationship between the stress gradient and the amount of deflection achieved is given by:

$$Δσ = \frac{2 zEt}{{L}^{2} ( 1 - {v}^{2} )}$$

where E is Young's modulus (˜270 GPa for silicon nitride), t is the thickness of the spring and v is Poisson's ratio (˜0.27 for silicon nitride). If spring 405 or 410 is made from low pressure chemical vapor deposited (LPCVD) silicon nitride, stress gradient Δσ is a byproduct of the deposition process. Stress gradients may be designed into other materials systems and are dependent upon deposition rate, surface mobility, film thickness and other parameters.

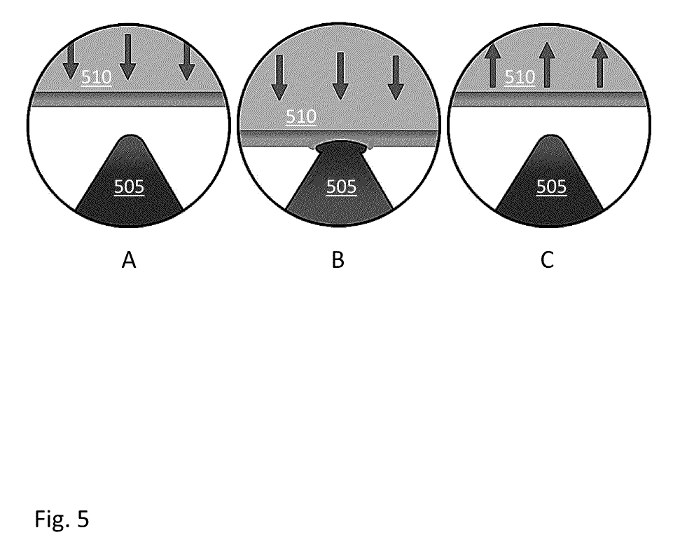

FIGS. 5A, 5B, and 5C show the tip of a MEMS micro-spring as it comes in contact with, and departs from, a surface. In FIGS. 5, spring tip 505 approaches (A), contacts (B), and departs from (C), surface 510. If the contact is elastic, the shape of the tip is restored when it is removed from contact with the surface. If both the tip and the surface are coated with gold, then the radius of the contact is given by:

$${r}_{contact} = \sqrt[3]{\frac{3 {F}_{contact} {r}_{tip} ( 1 - {v}^{2} )}{2 {E}_{gold}}}$$

where F_{contact} is the contact force, rₜᵢₚ is the radius of the spring tip, v is Poisson's ratio (˜0.44 for gold), and E is Young's modulus (˜78 GPa for gold). The resistance of the contact between the spring tip and the surface is a function of the contact radius, which in turn depends on the contact force.

MEMS ribbons in an optical ribbon modulator exhibit mechanical response times of ˜100 ns. If the maximum allowable electrical response time is approximately one third of the mechanical response time or ˜30 ns, then the corresponding maximum allowable contact resistance of the micro-spring to surface connection is 4 MΩ based on the capacitance of a ribbon. Thus low resistance is not a requirement for MEMS micro-springs used as interconnects to MEMS optical ribbon devices.

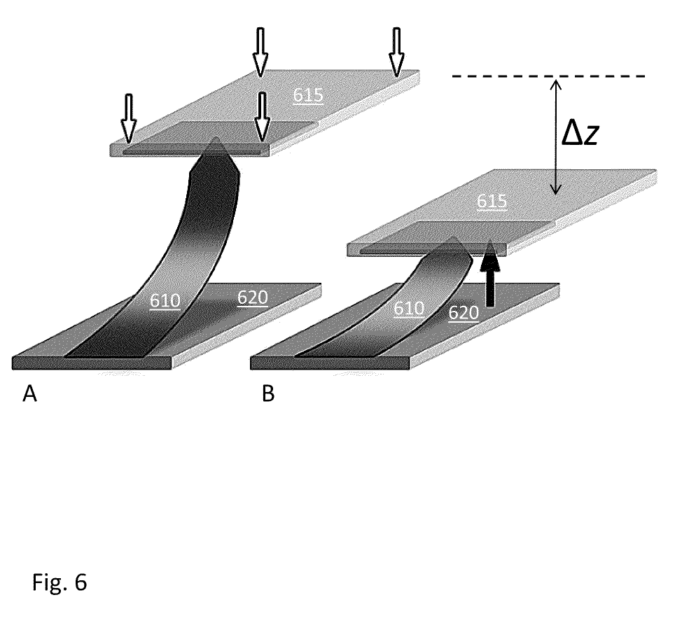

FIGS. 6A and 6B show a MEMS micro-spring in contact with a surface. In FIG. 6 MEMS micro-spring 610 is shown in contact with chip 615 for two different spring deflections caused by pressing the chip toward substrate 620 of spring 610. The force exerted by the spring is related to its spring constant, k, by F=k(Δz). Spring constant k is given by:

$$k = \frac{{Ewt}^{3}}{4 {L}^{3} ( 1 - {v}^{2} )}$$

where L, w and t are the length, width and thickness of the micro-spring, E is Young's modulus (˜270 GPa for silicon nitride) and v is Poisson's ratio (˜0.27 for silicon nitride).

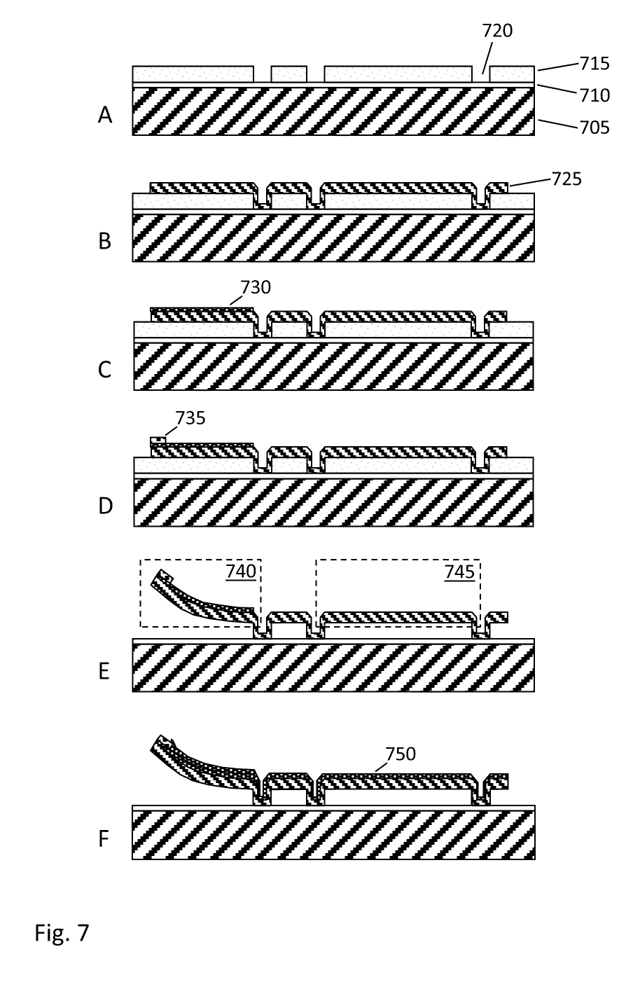

FIGS. 7A-7F are process steps for making MEMS micro-springs with post-release metallization. Although approximate actual thicknesses and specific materials are mentioned in the description of process steps, those skilled in the art will recognize that variations of materials, thicknesses and other parameters are possible and may be desirable to optimize a particular process for a particular application. In FIG. 7A a 1000 Å thick electrical isolation layer 710 of silicon oxide has been grown on silicon substrate 705. 7000 Å thick sacrificial amorphous silicon layer 715 is deposited using low pressure chemical vapor deposition (LPCVD) and patterned with standard lithographic techniques, leaving areas of exposed silicon oxide such as 720 where mechanical anchors will be formed. In FIG. 7B a 1000 Å thick mechanical layer 725 of silicon nitride deposited by LPCVD is added. In FIG. 7C 500 Å of aluminum 730 has been evaporated on an area that will later become a micro-spring. In FIG. 7D 200 Å of chrome is followed by 2000 Å of gold 735 near the tip of the micro-spring. Areas where metal is not desired are protected by shadow masks during evaporation steps. FIG. 7E shows the result of removing sacrificial amorphous silicon layer 715 and thereby releasing silicon nitride mechanical structures by etching in a xenon difluoride etcher. In FIG. 7E dashed box 740 encloses a released micro-spring while dashed box 745 encloses a MEMS ribbon structure manufactured simultaneously. Finally, in FIG. 7F an electrical/optical (metal) layer 750 of aluminum is deposited to make the surface of the ribbon (within 745) highly reflective and responsive to electrostatic deflection.

FIGS. 7A-7F were described in terms of a process using silicon as a sacrificial layer and silicon nitride as a mechanical layer with a xenon difluoride release etch. Other materials systems can be used to make similar electromechanical structures, however. For example, silicon oxide can be used as a sacrificial layer and silicon as a mechanical layer with a hydrogen fluoride release etch. Glass or quartz may be used as a substrate material. Mechanical layer 725 may also comprise multiple dielectric layers in order to engineer the magnitude of its internal stress gradient. Silicon nitride tensile stress layers may be paired with silicon oxide compressive stress layers, for example.

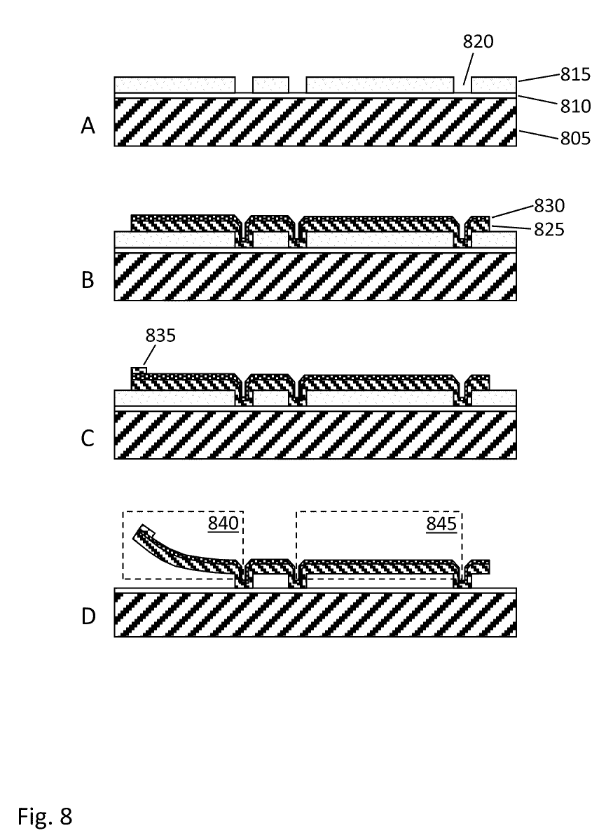

Further, in the process of FIGS. 7A-7F, ribbons and micro-springs are metalized (layer 750) after mechanical structures are released from the substrate via the removal of sacrificial layers. It is possible, however, to metalize the micro-springs and ribbons before releasing mechanical structures as shown in FIG. 8.

FIGS. 8A-8D are process steps for making MEMS micro-springs with pre-release metallization. Although approximate actual thicknesses and specific materials are mentioned in the description of process steps, those skilled in the art will recognize that variations of materials, thicknesses and other parameters are possible and may be desirable to optimize a particular process for a particular application. In FIG. 8A a 1000 Å thick electrical isolation layer 810 of silicon oxide has been grown on silicon substrate 805. 7000 Å thick sacrificial amorphous silicon layer 815 is deposited using low pressure chemical vapor deposition (LPCVD) and patterned with standard lithographic techniques, leaving areas of exposed silicon oxide such as 820 where mechanical anchors will be formed. FIG. 8B shows the addition of a mechanical layer 825 of LPCVD silicon nitride and an electrical/optical (metal) layer 830 of evaporated aluminum. A layer 835 of gold (including a chrome sticking layer) is evaporated over the tip of a nascent micro-spring in FIG. 8C. Finally, FIG. 8D shows the effect of releasing the micro-spring (enclosed within dashed box 840) and ribbon (enclosed within 845) by removing amorphous silicon layer 815 with a xenon difluoride etch. Thus ribbon structures and their micro-spring interconnect mechanisms are fabricated simultaneously using the same process steps.

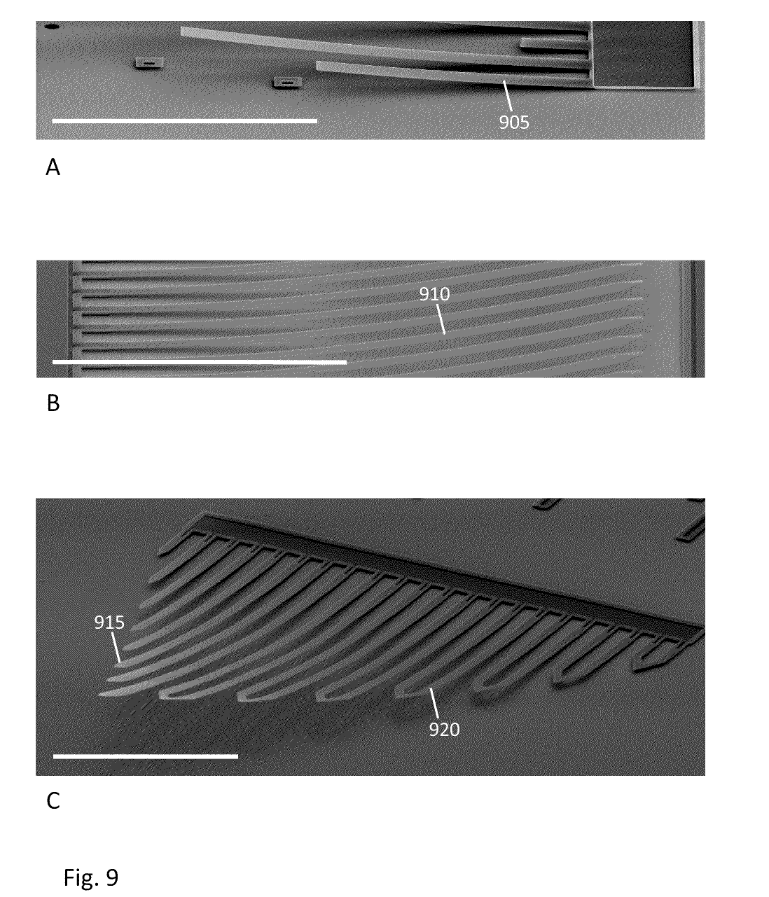

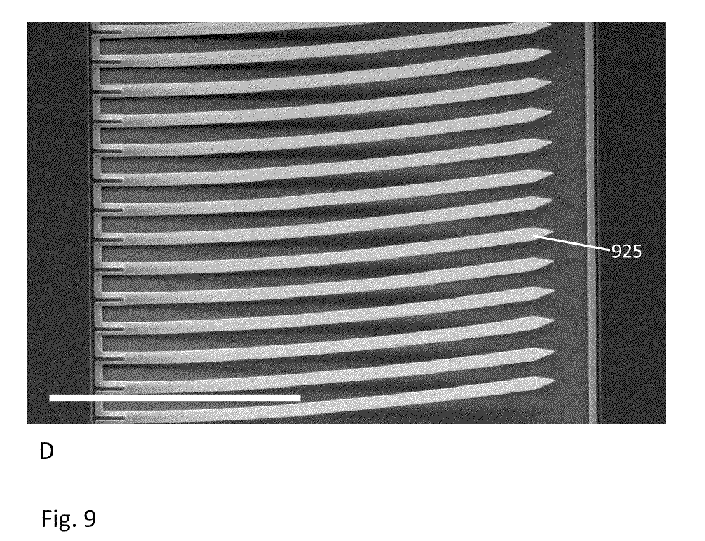

FIGS. 9A-9D are SEM images of MEMS micro-springs made by the processes of FIGS. 7 or 8. In each of the images the scale bar in the lower left corner is 50 μm long. FIG. 9A shows an assortment of micro-springs (e.g. 905) of different lengths having square tips while FIG. 9B shows an array of micro-springs (e.g. 910) all of the same length with pointed tips. FIG. 9C shows a test structure that includes single-leg (915) and double-leg (920) micro-springs. Finally, FIG. 9D shows an array of equal-length, pointed micro-springs (e.g. 925) in which the pitch or distance from one spring to the next is approximately 8 μm.

MEMS chip-to-chip interconnect systems based on metal-coated insulating MEMS micro-springs are suited for applications that do not require low-resistance connections such as MEMS optical ribbon modulators. MEMS micro-springs are a simple solution that allow interconnects to be fabricated simultaneously with ribbon structures. While the description refers to “CMOS”, electronic chips created by any standard process (e.g. bipolar-CMOS, emitter coupled logic, etc.) are easily compatible with micro-spring interconnects.

As one skilled in the art will readily appreciate from the disclosure of the embodiments herein, processes, machines, manufacture, means, methods, or steps, presently existing or later to be developed that perform substantially the same function or achieve substantially the same result as the corresponding embodiments described herein may be utilized according to the present invention. Accordingly, the appended claims are intended to include within their scope such processes, machines, manufacture, means, methods, or steps.

The above description of illustrated embodiments of the systems and methods is not intended to be exhaustive or to limit the systems and methods to the precise form disclosed. While specific embodiments of, and examples for, the systems and methods are described herein for illustrative purposes, various equivalent modifications are possible within the scope of the systems and methods, as those skilled in the relevant art will recognize. The teachings of the systems and methods provided herein can be applied to other systems and methods, not only for the systems and methods described above.

In general, in the following claims, the terms used should not be construed to limit the systems and methods to the specific embodiments disclosed in the specification and the claims, but should be construed to include all systems that operate under the claims. Accordingly, the systems and methods are not limited by the disclosure, but instead the scope of the systems and methods are to be determined entirely by the claims.

What is claimed is:

1. A micro-electromechanical device comprising:
a ribbon; and,
an micro-spring coated with a conductive metal layer, wherein the ribbon and the micro-spring are fabricated on a common substrate.

2. The device of claim 1 wherein the micro-spring is an insulator.

3. The device of claim 1 further comprising an electronic chip in contact with the micro-spring wherein the electronic chip makes electrical contact with the conductive metal layer.

4. The device of claim 1 fabricated by a process comprising:
providing a substrate;
depositing an electrical isolation layer on the substrate;
depositing a sacrificial layer on the isolation layer;
patterning the sacrificial layer using photolithography;
depositing a mechanical layer on the sacrificial layer;
depositing a metal layer on the mechanical layer;
removing the sacrificial layer.

5. The device of claim 4 wherein the mechanical layer is an insulator.

6. The device of claim 4 wherein the electrical isolation layer is silicon oxide, the sacrificial layer is amorphous silicon, the mechanical layer is silicon nitride, and the metal layer is aluminum.

7. The device of claim 6 wherein removing the sacrificial layer is accomplished by etching with xenon difluoride.

8. The device of claim 4 wherein the substrate is silicon, the electrical isolation and sacrificial layers are silicon oxide, and the metal layer is aluminum.

9. The device of claim 8 wherein removing the sacrificial layer is accomplished by etching with hydrogen fluoride.
